(19) United States
(12) Patent Application Publication
(10) Pub. No.: US 2011/0084280 A1
(43) Pub. Date: Apr. 14, 2011

(54) THIN FILM TRANSISTOR SUBSTRATE, THIN FILM TRANSISTOR TYPE LIQUID CRYSTAL DISPLAY DEVICE, AND METHOD FOR MANUFACTURING THIN FILM TRANSISTOR SUBSTRATE

(75) Inventors: Tokuyuki NAKAYAMA, ICHIKAWA-SHI (JP); Yoshiyuki ABE, Ichikawa-shi (JP)

(73) Assignee: SUMITOMO METAL MINING CO., LTD., TOKYO (JP)

(21) Appl. No.: 12/904,411

(22) Filed: Oct. 14, 2010

Related U.S. Application Data
(63) Continuation of application No. PCT/JP2009/057446, filed on Apr. 13, 2009.

(30) Foreign Application Priority Data
Apr. 16, 2008 (JP) 2008106927
Dec. 26, 2008 (JP) 2008332317

(51) Int. Cl. H01L 33/42; H01L 29/786; H01L 21/283

(52) U.S. Cl. 257/59; 257/57; 438/609; 257/E29.296; 257/E33.064; 257/E21.159

(57) ABSTRACT

There are provided: a thin film transistor substrate provided with an amorphous transparent conductive film in which residue due to etching hardly occurs; a liquid crystal display device which utilizes the thin film transistor substrate; and a method for manufacturing a thin film transistor substrate in which the thin film transistor substrate can be efficiently obtained.

Provided is a thin film transistor substrate in which there is provided a transparent substrate, on the transparent substrate there are formed a gate electrode, a semiconductor layer, a source electrode, a drain electrode, a transparent pixel electrode, and a transparent electrode, and the transparent pixel electrode is formed with a transparent conductive film and is electrically connected to the source electrode or the drain electrode, wherein the transparent conductive film which constitutes the transparent pixel electrode is composed of an indium oxide containing gallium.

### TECHNICAL FIELD

The present invention relates to a thin film transistor substrate which drives liquid crystals of a liquid crystal display device, a liquid crystal display device which uses the thin film transistor substrate, and a method for manufacturing the thin film transistor substrate.

### BACKGROUND ART

Dedicated research and development of liquid crystal display devices has been conventionally made, and particularly in recent years, this research and development is becoming more active since the first appearance of a liquid crystal display device for large size television sets. In order to drive liquid crystals of this type of liquid crystal display device, there is used a thin film transistor (TFT) substrate. This type of thin film transistor substrate is such that a gate electrode, a gate insulation film, a semiconductor layer, a source electrode and drain electrode composed of an aluminum material, a transparent pixel electrode, and a transparent electrode are formed on a transparent substrate in this order.

As the material of the transparent pixel electrode of this liquid crystal display device, in general, an indium oxide material, in particular, an indium oxide (indium tin oxide: ITO) which contains tin as a dopant is used. This is because ITO has superior electrical conductivity and transparency, and can undergo etching with strong acid (aqua regia, hydrochloric acid-based etchant, or the like).

The transparent pixel electrode which uses this type of ITO is formed by forming an ITO film on a large sized substrate by means of a sputtering method. However, there is a problem in that with an ITO target, when continuous film formation is conducted for a long period of time, nodules may be generated on the target surface, and abnormal electrical discharge may occur or a foreign substance may occur, causing the pixels to malfunction. Here, nodules refer to black colored depositions (protrusions) which occur in an erosion portion on the target surface except for a negligible portion in the deepest part of the erosion, as sputtering on the target progresses. In general, nodules are thought to be the remnants of sputtering rather than accumulated extraneous flying objects or the products of a reaction. Nodules cause abnormal electrical discharging such as arcing, and if nodules can be reduced, arcing can be suppressed (refer to Non-Patent Document 1).

Moreover, a conventional ITO film formed on a large size substrate by means of a sputtering method is a crystalline film. However, the state of the crystals thereof changes variously according to the state of substrate temperature, atmospheric gas, plasma density, or the like, and consequently there may be a mixture of portions having different crystallinity on the same substrate in some cases. Also in those cases where a strong acid etchant is used, there is a problem in that this mixture causes etching defects (conduction with an adjacent electrode, thinning of pixel electrodes due to over etching, pixel defects due to etching residue, and the like) which lead to problems in liquid crystal driving. This is because a part of a portion of the ITO film having a high level of crystallinity is partially undissolved and remains, even with the strong etchant, and it becomes a residue. Furthermore, a portion of the ITO film having a low level of crystallinity is over-etched by the strong acid etchant, and this may cause erosion in the aluminum wiring material of the source electrode and drain electrode.

In order to solve the above problems which occur when conducting etching, for example, Patent Document 1 discloses a method for improving aluminum elution which occurs in etching, by conducting film formation at a substrate temperature not more than 150° C. and making an ITO pixel electrode film amorphous to thereby increase the ITO/Al etching speed ratio with respect to a HCl—HNO₃—H₂O based etchant. However, in a case of an amorphous ITO, the level of adhesion with a foundation substrate is often reduced, and it may cause the resistance of contact with the aluminum wiring material to increase in some cases. Moreover, an amorphous ITO formed at a substrate temperature not more than 150° C. contains microcrystals, which cannot be detected in X-ray diffraction measurement. Consequently there is a possibility that a residue may occur in etching with an etchant containing a strong acid.

Furthermore, there has been investigated a method in which when forming an ITO film, water or hydrogen is added to a sputtering gas to thereby form an amorphous-state ITO which does not contain the above microcrystals, and this formed ITO film is etched and then heated so as to be crystallized. In this case, the problem of residue occurrence in etching is solved. However, if water or hydrogen is added when film formation is conducted, there will be a problem in that the adhesion of the film with the foundation substrate is reduced, or the surface of the ITO target is reduced and a large amount of nodules consequently occur.

On the other hand, there are some cases in a thin film transistor substrate where the aluminum wiring material may be eroded due to the aluminum wiring material of the source electrode and drain electrode being in contact with the ITO. Furthermore, depending on the thermal history in a step of crystallizing amorphous ITO or in subsequent steps, fine surface irregularities called hillocks may occur on the periphery of the aluminum wiring layer, causing a short circuit to occur between wirings in some cases. In order to prevent these problems, a barrier metal film composed of materials such as chrome, molybdenum, titanium, and tantalum needs to be formed on the aluminum wiring of the source electrode and drain electrode.

As an alternative material to ITO which has these types of problems, there has been used an indium zinc oxide. This indium zinc oxide is highly useful because it can form a virtually complete amorphous film when film formation is conducted; can be etched with an oxalic acid based etchant, which is weak acid; and can also be etched with a mixed acid composed of phosphoric acid, acetic acid, and nitric acid, or a di-ammonium cerium (IV) nitrate solution. Moreover, a target composed of this indium zinc oxide generates very low level of nodules, is capable of suppressing foreign substance occurrence on the film, and it is therefore a useful target.

As an example of the above target containing indium zinc oxide, Patent Document 2 discloses a target composed of an oxide sintered body containing a hexagonal crystal lamellar compound expressed by the general formula In₂O₃(ZnO)ₘ (wherein m=2 to 20). With use of this target, it is possible to form a transparent conductive film having superior moisture resistance (durability).

Moreover, as an example of the above transparent conductive film containing indium zinc oxide, Patent Document 3 discloses a method in which a coating solution, which is prepared by dissolving an indium compound and a zinc compound in the presence of alkanolamine, is coated on a substrate and is sintered, and it then undergoes a reduction treatment, to thereby manufacture a transparent conductive film. It is disclosed in Patent Document 3 that it is also possible to obtain a transparent conductive film having superior moisture resistance (durability) in this method for manufacturing a transparent conductive film.

Furthermore, as an example of a method for etching the above transparent conductive film containing indium zinc oxide, Patent Document 4 discloses a liquid crystal display device manufacturing method in which a transparent conductive film composed of In₂O₃—ZnO is etched with an oxalic acid solution to thereby form a pixel electrode. It is disclosed in Patent Document 4 that according to this liquid crystal display manufacturing method, etching is conducted using an oxalic acid solution and therefore a pattern of a pixel electrode can be easily formed, consequently allowing yield rate to improve.

However, indium zinc oxide has a problem in that a particular type of hexagonal crystal lamellar compound needs to be produced from indium oxide and zinc oxide, and therefore the target manufacturing step becomes complicated, consequently increasing the cost.

Moreover, a film composed of indium zinc oxide has a disadvantage in that the transmission thereof on the visible range short wavelength side of wavelength 400 nm to 450 nm, that is, blue light transmission, is low.

Furthermore, also in those cases where indium zinc oxide is used as the material of a transparent pixel electrode, due to problems related to hillocks and other manufacturing related reasons, the structure is made to contain a barrier metal in many cases as with the case of ITO. However, in this case, it is known that the contact resistance between the indium zinc oxide and the barrier metal often increases.

In contrast, Patent Document 5 proposes, as an alternative material to an ITO and indium zinc oxide material, a transparent conductive film with use of an indium based material for a transparent pixel electrode material which contains indium oxide as its primary component and further contains one or more types of oxides selected from tungsten oxide, molybdenum oxide, nickel oxide, and niobium oxide.

This indium oxide based material, even in a case of forming an amorphous film therefrom, still has a problem of residue occurrence when etched with a weak acid etchant, although it occurs less frequently compared to ITO. Although this material has a rather higher film crystallization temperature compared to ITO, it is not as high as that of an indium zinc compound, and the film partially becomes crystallized, depending on the film formation process. Also in this case, residue occurrence in the etching process becomes a problem.
[Patent Document 1] Japanese Unexamined Patent Publication No. S63-184726
[Patent Document 2] Japanese Unexamined Patent Publication No. H06-234565
[Patent Document 3] Japanese Unexamined Patent Publication No. H06-187832
[Patent Document 4] Japanese Unexamined Patent Publication No. H11-264995
[Patent Document 5] Japanese Unexamined Patent Publication No. 2005-258115
[Patent Document 6] Japanese Unexamined Patent Publication No. H06-120503
[Non-Patent Document 1] “Technique of transparent conductive film (revised version 2)”, Ohmsha, Dec. 20, 2006, p. 184-193

### DISCLOSURE OF THE INVENTION

### Problem to be Solved by the Invention

The present invention takes the above circumstances into consideration, with an object of providing a transparent pixel electrode formed with a transparent conductive film such that nodule occurrence during sputtering can be suppressed in a manufacturing process, etching residue does not occur in the etching process even in a case of using a weak acid, and short-circuiting between electrodes and problems of liquid crystal driving, which are caused by these abnormalities in the film, hardly occur. Moreover, there is provided a transparent pixel electrode for which being in contact with the aluminum wiring material of the source electrode and drain electrode does not cause erosion to occur in the aluminum wiring material. There is also provided a transparent pixel electrode for which contact resistance does not increase between this electrode and the barrier metal for the aluminum wiring material of the source electrode and drain electrode.

### Means for Solving the Problems

As a result of earnestly conducting an investigation in order to solve the problems above, the present inventors have discovered that with a thin film transistor substrate on which there are formed a gate electrode, a semiconductor layer, a source electrode, a drain electrode, a transparent pixel electrode, and a transparent electrode, and the transparent pixel electrode is formed with a transparent conductive film and is electrically connected to the source electrode or the drain electrode, by using a transparent conductive film composed of an indium oxide containing gallium as a transparent conductive film of a transparent pixel electrode, the transparent pixel electrode can be easily patterned with an acidic etchant (etching liquid), and with the transparent pixel electrode, a transparent pixel electrode and the source electrode or drain electrode can be easily connected electrically without any problems. As a result, the present invention has been completed.

That is to say, a first aspect of the present invention is a thin film transistor substrate in which there is provided a transparent substrate, on the transparent substrate there are formed a gate electrode, a semiconductor layer, a source electrode, a drain electrode, a transparent pixel electrode, and a transparent electrode, and the transparent pixel electrode is formed with a transparent conductive film and is electrically connected to the source electrode or the drain electrode, wherein the transparent conductive film of the transparent pixel electrode is composed of an indium oxide which contains gallium.

The gallium content in the indium oxide containing gallium is preferably 0.10 to 0.35 in terms of the Ga/(In+Ga) atomic ratio.

Moreover, it is preferable that the transparent conductive film composed of the indium oxide containing gallium is amorphous.

A second aspect of the present invention is a thin film transistor substrate as with the first aspect above, wherein the transparent conductive film which constitutes the transparent pixel electrode thereof is composed of an indium oxide containing gallium and tin.

It is preferable that the gallium content in the indium oxide containing gallium and tin is 0.02 to 0.30 in terms of the Ga/(In+Ga+Sn) atomic ratio, and the tin content is 0.01 to 0.11 in terms of the Sn/(In+Ga+Sn) atomic ratio.

It is preferable that the transparent conductive film composed of the indium oxide containing gallium and tin is crystallized.

In any of the aspects of the present invention, it is preferable that the transparent conductive film does not contain zinc.

A third aspect of the present invention is a thin film transistor type liquid crystal display device, wherein there are provided the above thin film transistor substrate according to the present invention, a color filter substrate having a coloring pattern of a plurality of colors provided thereon, and a liquid crystal layer sandwiched between the thin film transistor substrate and the color filter substrate.

A fourth aspect of the present invention is a method for manufacturing a thin film transistor substrate in which there is provided a transparent substrate, on the transparent substrate there are formed a gate electrode, a semiconductor layer, a source electrode, a drain electrode, a transparent pixel electrode, and a transparent electrode, and the transparent pixel electrode is formed with a transparent conductive film and is electrically connected to the source electrode or the drain electrode, wherein

there are included steps of: forming a film of an amorphous-state indium oxide containing gallium or a film of an amorphous-state indium oxide containing gallium and tin, to thereby form a transparent conductive layer; and etching the formed transparent conductive film with use of an acidic etchant to thereby form the transparent pixel electrode.

It is preferable that the etchant is acidic and is one which contains any one or more types of an oxalic acid, a mixed acid composed of phosphoric acid, acetic acid, and nitric acid, and a di-ammonium cerium (IV) nitrate.

Moreover, it is preferable that after a step of forming the transparent pixel electrode, there is included a step of performing heat treatment on the transparent conductive film at a temperature ranging from 200° C. to 500° C.

Furthermore, in a case where the transparent conductive film is formed with the amorphous-state indium oxide containing gallium, it is preferable that microcrystals are produced in the transparent conductive film and the amorphous state thereof is maintained.

On the other hand, in a case where the transparent conductive film is formed with the amorphous-state indium oxide containing gallium and tin, it is preferable that the transparent conductive film is made crystallized in the heat treatment.

In a case where a thin film transistor substrate is manufactured by the method of the present invention, it is preferable that the heat treatment is performed in an atmosphere which does not contain oxygen.

### EFFECT OF THE INVENTION

In the method for manufacturing a thin film transistor substrate of the present invention, as the transparent conductive film which constitutes the transparent pixel electrode, there is employed a transparent conductive film composed of an indium oxide containing gallium or an indium oxide containing gallium and tin.

Consequently, when manufacturing, the transparent pixel electrode can be formed using an acidic etchant, without etching residue occurring and without erosion occurring in the aluminum wiring material of the source electrode and drain electrode.

Moreover, by forming the transparent conductive film as an amorphous film, an etchant using a weak acid such as organic acid can be used, and even in this case, residue due to etching hardly occurs. Furthermore, nodules do not occur in a target, and film formation can be conducted without causing abnormal electrical discharges such as arcing. Therefore, this type of manufacturing method offers superior workability and is capable of improving yield rate.

Moreover, the thin film transistor substrate obtained in this type of manufacturing method has an effect in which there are no problems caused by film formation defects or etching defects, and the transparent pixel electrode being in contact with the aluminum wiring material of the source electrode and drain electrode does not cause erosion in the aluminum wiring material, or even in a case where a barrier metal film is formed on the wiring of the source electrode and the drain electrode, contact resistance does not increase.

By using this type of thin film transistor substrate, it is possible, at a high level of manufacturing efficiency, to obtain a highly reliable thin film transistor type liquid crystal display device.

### BRIEF DESCRIPTION OF THE DRAWINGS

FIG. 1 is a cross-sectional view of the vicinity of an a-Si TFT active matrix substrate of Examples 1 to 3 (a structure in which a barrier metal BM intervenes between a transparent conductive film and an Al wiring).

FIG. 2 is a cross-sectional view of the vicinity of an a-Si TFT active matrix substrate of Example 4 (a structure in which a barrier metal BM does not intervene between a transparent conductive film and an Al wiring).

### DESCRIPTION OF REFERENCE SYMBOLS

1 Glass substrate
2 Gate electrode
2a Gate electrode wiring
3 Gate insulation film: SiN film
4 a-Si:H(i) film
5 Channel protective layer: SiN film
6 a-Si:H(n) film
7 Source electrode
8 Drain electrode
9 Transparent conductive film (transparent pixel electrode)
10 Transparent resin resist
12 Contact hole
100 a-Si TFT active matrix substrate
200 a-Si TFT active matrix substrate
Al Aluminum wiring
BM Barrier metal (metal selected from Mo, Cr, Ti, and Ta)

### BEST MODE FOR CARRYING OUT THE INVENTION

A thin film transistor substrate of the present invention is a thin film transistor substrate in which there is provided a transparent substrate, on the transparent substrate there are formed a gate electrode, a semiconductor layer, a source electrode, a drain electrode, a transparent pixel electrode, and a transparent electrode, and the transparent pixel electrode is formed with a transparent conductive film and is electrically connected to the source electrode and the drain electrode.

The transparent conductive film which constitutes the transparent pixel electrode is characterized in that it is composed of an indium oxide containing gallium or an indium oxide containing gallium and tin.

### 1. Transparent Conductive Film

### (Composition)

In a thin film transistor substrate according to the first aspect of the present invention, the transparent conductive film used for the transparent pixel electrode is formed with an indium oxide containing gallium. As for the composition of the indium oxide containing gallium, the gallium content is preferably 0.10 to 0.35 in terms of the Ga/(In+Ga) atomic ratio. If the gallium content is lower than 0.10, there is a possibility that residue may occur when conducting etching. On the other hand, if it exceeds 0.35, the resistance value becomes high and consequently it may become inapplicable in some cases. However, in those cases where low-temperature polysilicon or the like, which has a high level of mobility, is used as the semiconductor layer, it is not limited to this, and application thereof may be possible where it exceeds 0.35 in some cases.

In a thin film transistor substrate according to the second aspect of the present invention, the transparent conductive film used for the transparent pixel electrode is formed with an indium oxide containing gallium and tin. By further adding tin to the indium oxide which contains gallium, it is possible to make the resistance of the transparent conductive film low.

As for the composition of the indium oxide containing gallium and tin, it is preferable that the gallium content is 0.02 to 0.30 in terms of the Ga/(In+Ga+Sn) atomic ratio, and the tin content is 0.01 to 0.11 in terms of the Sn/(In+Ga+Sn) atomic ratio. In a case where tin is contained, if the gallium content is lower than 0.02, etching residue becomes likely to occur. In contrast, if the gallium content exceeds 0.30, the resistance cannot be made sufficiently low. That is to say, the effective gallium content range shifts to the low gallium amount side, compared to the case where tin is not contained. Moreover, if the tin content is lower than 0.01, the resistance cannot be made sufficiently low, and further, if the tin content exceeds 0.11, residue and the like may occur when conducting etching in some cases.

As for either one of the indium oxide containing gallium and the indium oxide containing gallium and tin, even in a case of a crystalline film, it is possible to conduct etching without residue occurring, using an acidic etchant except weak acid etchants. However, it is preferably made an amorphous film when conducting film formation. With an amorphous transparent conductive film, it is possible to conduct etching with no residue occurring, using an etchant which contains a weak acid such as oxalic acid.

It is preferable that the transparent conductive film does not contain zinc. This is because if zinc is contained, then there will be a problem in that the resistance value increases, or light absorption in a wavelength region of 400 to 450 nm increases and consequently transmission becomes reduced. Moreover, in the thin film transistor substrate of the present invention, as a barrier metal (BM) of the aluminum wiring, chrome, molybdenum, titanium, or tantalum may be used in some cases. If zinc is contained, it is not preferable as it may cause a problem to occur where the contact resistance between the transparent conductive film and these barrier metals increases and the contact property consequently deteriorates.

### (Properties)

As mentioned above, the property of the transparent conductive film of the present invention may be either amorphous or crystalline. However, it is preferable that the transparent conductive film is formed so as to be an amorphous film, and the transparent conductive film after film formation undergoes heat treatment, to thereby change the property thereof.

In the transparent conductive film, which is formed with an indium oxide containing gallium, it is particularly preferable that after the heat treatment, the amorphous state thereof is still maintained without having it crystallized. In the amorphous-state transparent conductive film, there is created a state where microcrystals (extremely minute monocrystals) of an indium oxide phase having gallium dissolved therein which cannot be observed by means of X-ray diffraction, are produced.

It is thought that by bringing the property of the transparent conductive film into this type of state by means of heat treatment, carrier electrons increase due to oxygen deficiency, and in addition, simple defects which do not contribute to the production of carrier electrons, produced in the film formation conducted with low-level energy at the vicinity of room temperature are resolved, and this further contributes to the production of new carrier electrons (or contributes to improvement in mobility). Accordingly, it is possible to sufficiently exert the effect of a low-specific resistance. By maintaining the level of microcrystal production in the transparent conductive film at a level where the microcrystals cannot be observed by means of X-ray diffraction, light transmission on the short wavelength side of the visible light region, that is, light transmission on the wavelength of blue light region (400 to 450 nm) can be improved, and an improvement in transmission of the entire visible light region can be achieved as a result. The above microcrystals can be confirmed, using an AFM (atomic force microscope) or the like.

Furthermore, by maintaining the property of the transparent conductive film in an amorphous state, there can be obtained an effect in which the contact property with respect to the wiring of an aluminum alloy and the like and to a barrier metal such as molybdenum is also improved.

In a case of a transparent conductive film formed with an indium oxide containing gallium, it is not preferable that the transparent conductive film is entirely in a crystalline state. This is because if the film is entirely in a crystalline state, then due to the limitation of the crystal lattice, production of oxygen deficiency as much as in an amorphous state thereof is not permitted, carrier electrons are reduced, and the specific resistance increases. Moreover, a reduction in carrier electrons causes the apparent band gap to become small, and transmission becomes low consequently.

On the other hand, in a case of the transparent conductive film formed with an indium oxide containing gallium and tin, as with the indium oxide containing gallium, it may be in an amorphous state where microcrystals are present, and the effect thereof is similar to that of the transparent conductive film formed with the indium oxide containing gallium. However, it is more preferable that the amorphous-state transparent conductive film is crystallized by means of heat treatment to thereby bring the film into a crystalline state. This is because, by bringing this film into a crystalline state, light transmission of the wavelength in the blue light region (400 to 450 nm) can be similarly improved, and as a result, an improvement in the transmission of the entire visible light region can be achieved.

The improvement in the light transmission of the wavelength in the blue light region in the transparent conductive film can be described by the effect of a significant increase in carrier electrons in the crystallized film having tin added thereto. That is to say, an indium oxide phase is formed by crystallization, however, if tin is added here, tetravalent tin substitutes the trivalent indium (gallium) site, and thereby carrier electrons are further produced. Thus, in a case where carrier electrons are produced by site substitution of tin, the carrier electron concentration increases to approximately 10²¹ cm⁻³, including the carrier electrons produced by oxygen deficiency. With this type of increase in the carrier electron concentration, a part of the carrier electrons occupy the bottom part of the conduction-band, and the apparent band gap becomes greater than what it originally was. As also disclosed in Non-Patent Document 1, this type of phenomenon is called a Burstein-Moss shift. Thus, the level of energy required for optical transition of electrons becomes higher. That is to say, by having more light of the blue light region transmitted, an improvement in the transmission of the entire visible light region becomes possible as a result.

Moreover, the crystallized transparent conductive film shows a low resistance value comparable to that of ITO, and it has superior transparency. Furthermore, by crystallizing the transparent conductive film, there can be further obtained an effect of suppressing battery reaction, and there can be also obtained an effect in which etching defects such as breakage in the aluminum wiring hardly occur.

Thus, in the present invention, an amorphous-state transparent conductive film after film formation can be employed, however, it is preferable that the transparent conductive film is either in an amorphous state where microcrystals, which cannot be observed by means of X-ray diffraction, are present, or a crystalline state. With this type of property, the mechanism in which the transmission in the blue light region becomes high is presumed to be caused by the band gap of the transparent conductive film being large.

### (Film Thickness)

The film thickness of the transparent conductive film used for the thin film transistor substrate of the present invention is preferably 20 to 500 nm, more preferably 30 to 300 nm, and most preferably 30 to 200 nm. If the film thickness of the transparent conductive film is less than 20 nm, the surface resistance of the transparent conductive film may rise in some cases, and on the other hand, if the film thickness of the transparent conductive film exceeds 500 nm, transmission may be reduced and a problem may occur in working precision in some cases.

The transparent conductive film of the present invention having the characteristics described above may be joined with a source electrode and a drain electrode directly, or indirectly with a barrier metal intervening therebetween. While being the same amorphous film, the transparent conductive film of the present invention differs from an ITO film in that it hardly causes a battery reaction even in a state of being in contact with the aluminum which primarily constitutes the source electrode and the drain electrode. Moreover, even in a case where it is joined with a barrier metal intervening therebetween, unlike indium zinc oxide there is no such problem where the contact resistance becomes high. However, as described above, in a case where the transparent conductive film contains zinc, the contact resistance increases and the contact property becomes deteriorated. Similar results are observed also in those cases where the above elements taken as examples of the barrier metals are used as wiring materials rather than simply as barrier metals.

### 2. Manufacturing Transparent Conductive Film

### (Film Formation)

Next, there is described a method of forming the transparent conductive film, that is a method of forming, on a transparent substrate, a transparent conductive film which is composed of an indium oxide containing gallium or of an indium oxide containing gallium and tin.

First, on the entire area of the transparent substrate, there is formed either a transparent conductive film which is composed of an amorphous-state indium oxide containing gallium or a transparent conductive film composed of an indium oxide containing gallium and tin.

More specifically, a gate electrode, a semiconductor layer, a drain electrode, and a source electrode are sequentially formed on the transparent substrate by conducting lamination and etching by means of a commonly known method. Furthermore, above this, there are formed a transparent pixel electrode and a transparent electrode composed of the transparent conductive film, and this undergoes an etching treatment. Thereby, the transparent pixel electrode is formed so as to be electrically connected to one of the drain electrode and the source electrode. On the gate electrode, and the drain electrode and source electrode, there may be formed a barrier metal layer. Moreover, between the gate electrode and the semiconductor layer, there is formed a gate insulation film, in the intermediate part of the semiconductor layer, there is formed a channel protective layer, and on the gate insulation film, the drain electrode, and the source electrode, there is formed a protective film composed of a transparent resin resist.

As the method for forming the transparent conductive film, there may be used any commonly known method used for thin film formation, as long as the method is capable of formation of an amorphous-state film. For example, this film formation may be performed using methods such as a sputtering method and a vacuum vapor deposition method. However, use of a sputtering method is more preferred because the amount of particles or dust generated when conducting film formation is less compared to a vacuum vapor deposition method. Moreover, in a case of using a sputtering method, in order to form a high-quality amorphous film at a higher film formation rate, it is preferable that film formation is conducted using a DC magnetron sputtering method with a sputtering target of a sintered body composed of an indium oxide containing gallium or of a sintered body composed of an indium oxide containing gallium and tin.

In a case of forming a transparent conductive film composed of an indium oxide containing gallium, as the sputtering target, it is preferable that there is used a target formed with an oxide sintered body in which the gallium content is 0.10 to 0.35 in terms of the Ga/(In+Ga) atomic ratio, the In₂O₃ phase of a bixbyite type structure is the primary crystalline phase, and in this, the GaInO₃ phase of a β-Ga₂O₃ type structure or the GaInO₃ phase and the (Ga, In)₂O₃ phase are minutely dispersed as crystal grains of an average grain diameter of 5 μm or less.

On the other hand, in a case of forming a transparent conductive film composed of an indium oxide containing gallium and tin, as the sputtering target, it is preferable that there is used a target formed with an oxide sintered body in which the gallium content is 0.02 to 0.30 in terms of the Ga/(In+Ga+Sn) atomic ratio, the tin content is 0.01 to 0.11 in terms of the Sn/(In+Ga+Sn) atomic ratio, the In₂O₃ phase of a bixbyite type structure is similarly the primary crystalline phase, and in this, the GaInO₃ phase of a β-Ga₂O₃ type structure or the GaInO₃ phase and the (Ga, In)₂O₃ phase are minutely dispersed as crystal grains of an average grain diameter of 5 μm or less.

It is thought that the majority of the Sn substitutes the Ga or In site in the GaInO₃ phase. In those cases where Sn which does not substitute them for a reason that the solid solubility limit is exceeded with respect to the GaInO₃ phase or locally uneven-composition portions are created during the process of manufacturing the sintered body, a tetragonal composite oxide phase expressed in the general formula as: Ga₃₊ₓIn₅₊ₓSn₂O₁₆(0.3<x<1.5) may be produced to a certain degree in some cases. However, it is preferable that this phase is also minutely dispersed as crystal grains of an average grain diameter of 5 μm or less.

The above sintered body used for a sputtering target may be obtained such that: a raw material powder of an average grain diameter of 1 μm or less containing an indium oxide powder and gallium oxide powder is mixed, or a tin powder of an average grain diameter of 1 μm or less is added to and mixed with this raw material powder; this is sintered for 10 to 30 hours at a temperature ranging from 1,250° C. to 1,450° C. within an atmosphere having oxygen therein by means of a normal pressure sintering method, to thereby sinter the formed body obtained by shape-forming the mixed powder; or shape forming and sintering are conducted for 1 to 10 hours at a temperature ranging from 700° C. to 950° C. under a pressure of 2.45 MPa to 29.40 MPa within an inactive gas atmosphere or a vacuum atmosphere by means of a hot pressing method, to thereby sinter the mixed powder.

More specifically, the oxide sintered body of the present invention needs to use, as raw material powders, an indium oxide powder, and a gallium oxide power or a tin oxide power with an average grain diameter respectively adjusted to 1 μm or less. As the structure of the oxide sintered body of the present invention, there needs to be a structure in which the In₂O₃ phase is the primary phase, which exists together with a microscopic structure composed of the GaInO₃ phase, or the GaInO₃ phase and (Ga, In)₂O₃ phase, of which the average grain diameter of the crystal grains is 5 μm or less. The more preferred structure is such that the crystal grains composed of the GaInO₃ phase, or the GaInO₃ phase and (Ga, In)₂O₃ are dispersed minutely in the primary phase, and the average grain diameter is 3 μm or less. In a case where tin oxide is added, it is preferable that the other composite oxide phase, which may occur in the oxide sintered body, such as the Ga_{2.4}In_{5.6}Sn₂O₁₆ phase, Ga₂In₆Sn₂O₁₆ phase, and Ga_{1.6}In_{6.4}Sn₂O₁₆ phase, has a similar microscopic structure.

In order to form this type of microscopic structure, the average grain diameter of the raw material powders needs to be adjusted to 1 μm or less. If an indium oxide powder or gallium oxide powder with an average grain diameter exceeding 1 μm are used for the raw material powders, the average grain diameter of the crystal grains composed of the GaInO₃ phase or of the GaInO₃ phase and (Ga, In)₂O₃ phase, which is present in the obtained oxide sintered body together with the In₂O₃ phase serving as the primary phase, exceeds 5 μm. Large crystal grains of the GaInO₃ phase, or the GaInO₃ phase and (Ga, In)₂O₃ phase, the average grain diameter of which exceeds 5 μm, are cannot be sputtered easily. Therefore, if sputtering is continued, it becomes a comparatively large residue on the target surface, and this becomes the origin of nodules, consequently causing abnormal electrical discharges such as arcing.

The indium oxide powder is a raw material for ITO (indium/tin oxide), and development of a micro indium oxide powder with a high level of sintering property, together with improvements in ITO is progressing. Also, up until today, a large amount of indium oxide powder is used as an ITO raw material, and it is therefore easy to source a raw material powder with an average grain diameter of 1 μm or less. However, compared to the indium oxide powder, the amount of the gallium oxide powder used is low, and it is therefore difficult to source this as a raw material powder with an average grain diameter of 1 μm or less. Consequently, a coarse gallium oxide powder needs to be pulverized to an average grain diameter of 1 μm or less. Moreover, the tin powder, which is added as necessary, is in a state similar to that of the indium oxide powder, and it is therefore easy to source this as a raw material powder with an average grain diameter of 1 μm or less.

In order to obtain the oxide sintered body of the present invention, having mixed the raw material powder containing the indium oxide powder and gallium oxide powder, the mixed powder is shape-formed, and then the shape-formed body is sintered by means of a normal pressure sintering method, or the mixed powder is shape-formed and sintered by means of a hot pressing method. A normal pressure sintering method is a preferred method because it is a simple and industrially favorable method, however, a hot pressing method may be used as necessary.

In the case of using the normal pressure sintering method, a shape-formed body is fabricated first. The raw material powder is placed in a resin-made pot, and it is then mixed with a binder (PVA for example) and the like on a wet type ball mill or the like. It is preferable that the average grain diameter of the crystal grains composed of the GaInO₃ phase and (Ga, In)₂O₃ phase, which is present together with the In₂O₃ serving as the primary phase of the present invention, is 5 μm or less, and in order to obtain an oxide sintered body in which the crystal grains are minutely dispersed, the above mixing process on a ball mill is performed for 18 hours or longer. At this time, as the ball for mixing, there may be used a hard ZrO₂ ball. After mixing, the slurry is taken out, and then filtration, drying, and granulation are performed. Then, the obtained grains are subjected to cold isostatic pressing with a pressure of approximately 9.8 MPa (0.1 ton/cm²) to 294 MPa (3 ton/cm²) for shape forming to thereby provide a shape-formed body.

In the sintering step of the normal pressure sintering method, heat application is conducted within a predetermined temperature range in an atmosphere having oxygen therein. The temperature range is determined, depending on whether the sintered body is for sputtering, for ion plating, or for vapor deposition. If it is for sputtering, sintering is conducted at a temperature ranging from 1,250 to 1,450° C., and more preferably at a temperature ranging from 1,300 to 1,400° C. in an atmosphere where oxygen gas is introduced into the air within the sintering furnace. The preferred amount of time for sintering is 10 to 30 hours, and more preferably 15 to 25 hours.

On the other hand, if the sintered body is to be used for ion plating or vapor deposition, the shape-formed body is sintered for 10 to 30 hours at a temperature ranging from 1,000 to 1,200° C. within an atmosphere having oxygen therein. It is more preferable that sintering is conducted at a temperature ranging from 1,000 to 1,100° C. in an atmosphere where oxygen gas is introduced into the air within the sintering furnace. The preferred amount of time for sintering is 15 to 25 hours.

With a sintering temperature within the above range, and with use of the indium oxide powder and gallium oxide powder with the average grain diameter thereof adjusted to 1 μm or less as the raw material powder, it is possible to obtain a dense oxide sintered body in which crystal grains composed of the GaInO₃ phase or the GaInO₃ phase and (Ga, In)₂O₃ phase with an average crystal grain diameter of 5 μm or less, and more preferably 3 μm or less, are minutely dispersed in the In₂O₃ phase matrix.

If the sintering temperature is too low, the sintering reaction will not progress sufficiently. In particular, in order to obtain an oxide sintered body with a density of 6.0 g/cm³, 1,250° C. is preferred. On the other hand, if the sintering temperature exceeds 1,450° C., formation of the (Ga, In)₂O₃ phase becomes significant and the volume ratio between the In₂O₃ phase and GaInO₃ phase becomes reduced. As a result, it becomes difficult to control the oxide sintered body so as to be the minutely dispersed structure described above.

A preferred sintering atmosphere is an atmosphere having oxygen therein, and more preferably an atmosphere where oxygen is introduced into the air within the sintering furnace. The presence of oxygen in sintering enables a high level of densification of the oxide sintered body. When raising the temperature to the sintering temperature, in order to prevent cracks in the sintered body and cause the debinder process to progress, it is preferable that the rate of temperature increase is made within a range of 0.2 to 5° C./min. Moreover, different temperature increase rates may be combined to raise the temperature to the sintering temperature as necessary. In the process of increasing the temperature, the temperature may be maintained at a specific temperature for a certain period of time in order to cause the debinder process and the sintering process to progress. When conducting cooling after sintering, it is preferable that the oxygen introduction is stopped, and the temperature is lowered to 1,000° C. at a rate of 0.2 to 5° C./min, in particular, at a temperature lowering rate within a range from 0.2° C./min or higher to 1° C./min or lower.

In a case of employing a hot pressing method, the mixed powder is shaped-formed and sintered within an inactive gas atmosphere or a vacuum atmosphere for 1 to 10 hours at a temperature ranging from 700 to 950° C. and under a pressure ranging from 2.45 to 29.40 MPa. With the hot pressing method, it is possible to reduce the oxygen content within the sintered body compared to the above normal pressure sintering method, because the raw material powder of the oxide sintered body is shape-formed and sintered within a reduction atmosphere. However, attention is required because at a high temperature exceeding 950° C., indium oxide is reduced, and it is melted as metallic indium.

Here is an example of conditions for manufacturing an oxide sintered body by means of a hot pressing method. That is to say, an indium oxide powder with an average grain diameter of 1 μm or less and a gallium oxide powder with an average grain diameter of 1 μm or less, or these powders and a tin oxide powder with an average grain diameter of 1 μm or less are taken as raw material powders, and these powders are prepared to a predetermined ratio.

The prepared raw material powders are sufficiently mixed and granulated as with the case of the ball mill mixing in the normal pressure sintering method, for a preferred mixing time of 18 hours or longer. Next, the granulated mixed powder is supplied into a carbon container, and it is sintered by means of a hot pressing method. The sintering temperature may be 700 to 950° C., the sintering pressure may be 2.45 MPa to 29.40 MPa (25 to 300 kgf/cm²), and the sintering time may be approximately 1 to 10 hours. The atmosphere during the hot pressing process is preferably an inactive gas such as argon or a vacuum atmosphere.

In a case of obtaining a sputtering target, it is more preferable that the sintering temperature is 800 to 900° C., the sintering pressure is 9.80 to 29.40 MPa (100 to 300 kgf/cm²), and the sintering time is 1 to 3 hours. Moreover, in a case of obtaining a target for ion plating or vapor deposition, it is more preferable that the sintering temperature is 700 to 800° C., the sintering pressure is 2.45 to 9.80 MPa (25 to 100 kgf/cm²), and the sintering time is 1 to 3 hours.

The oxide sintered body used in the present invention is such that the sintered density thereof is preferably 6.3 g/cm³ or higher if it is used as a target for sputtering. In contrast, the sintered density is preferably in a range from 3.4 to 5.5 g/cm³ if it is used as a target for ion plating or vapor deposition.

With use of a target having this type of structure, formation of an amorphous film becomes easy. Furthermore, if this type of target is used, almost no nodules occur.

In those cases where the transparent conductive film is formed on a substrate by means of a sputtering method, a direct-current sputtering is useful because the level of thermal influence is low when conducting film formation, and film formation can be conducted at high speed. In order to conduct film formation by means of the direct-current sputtering, it is preferable that a mixed gas prepared with an inactive gas and oxygen, in particular, a mixed gas prepared with argon and oxygen is used as the sputtering gas. Moreover, the pressure within the chamber of the sputtering apparatus is preferably 0.1 to 1 Pa, and in particular, 0.2 to 0.8 Pa when conducting sputtering.

In the present invention, for example, it is possible to carry out pre-sputtering in which: having vacuum evacuated to 2×10⁻⁴ Pa or lower, a mixed gas of argon and oxygen is introduced; the gas pressure is set to 0.2 to 0.5 Pa; and direct-current power is applied so that the direct-current power with respect to the area of the target, that is, the direct-current power density is within a range of 1 to 3 W/cm², to generate direct-current plasma. It is preferable that after having performed this pre-sputtering for 5 to 30 minutes, the substrate position is adjusted as necessary, and then sputtering is performed.

Moreover, similar transparent conductive film formation is also possible in a case where an ion-plating target (may also be referred to as a tablet or pellet) fabricated from the above oxide sintered body is used.

As described above, in an ion plating method, if an electron beam or heat generated by arc discharge is irradiated on the target serving as a vapor source, the temperature of the portion exposed to the irradiation locally becomes high, and vapor particles evaporate and get accumulated on the substrate. At this time, the vapor particles are ionized using an electron beam or arch discharge. There are various types of ionization methods, and among them, a high density plasma-enhanced evaporation method (HDPE method), which uses a plasma generating apparatus (plasma gun), is suitable for forming a high-quality transparent conductive film. In this method, arc discharge with use of a plasma gun is utilized. Arc discharge is maintained between the cathode and the crucible (anode) of the vapor source provided within the plasma gun. Electrons discharged from the cathode are introduced into the crucible by the magnetic field bias, and are irradiated in a concentrated manner on a local area of the target prepared inside the crucible. This electron beam causes the vapor particles to evaporate from the portion, the temperature of which has locally become high, and to accumulate on the substrate. The vaporized vapor particles and O₂ gas introduced as a reactive gas are ionized and activated within this plasma, and it is consequently possible to fabricate a high-quality transparent conductive film.

The transparent conductive film is formed where the substrate temperature is preferably in a range from room temperature to 180° C., and more preferably in a range from room temperature to 150° C. Moreover, since the transparent conductive film has a high crystallization temperature, which is 220° C. or higher, if film formation is conducted within this temperature range, it is possible to reliably obtain an amorphous film in a more complete amorphous state. It is thought that this is because the crystallization temperature of the indium oxide containing gallium or the indium oxide containing gallium and tin, is high.

The reason for the above substrate temperature range when film formation is conducted is that, in order to control the substrate temperature at room temperature or lower, cooling is required and consequently energy loss occurs, and further the temperature control thereof may cause a reduction in manufacturing efficiency in some cases. On the other hand, in a case where the substrate temperature exceeds 180° C., the transparent conductive film may become partially crystallized in some cases, and etching may not be conducted with an etchant containing a weak acid such as oxalic acid in some cases. Furthermore, water or hydrogen may be added to the atmosphere gas when forming the film. Thereby, it becomes easier to etch the formed transparent conductive film, using an etchant containing a weak acid such as oxalic acid, and residue can be further reduced. Also in this case, the level of the film adhesion with respect to the foundation substrate will not be reduced.

### (Etching)

It is preferable that the acidic etchant (etching liquid) is weak acid. This is because in those cases where etching is conducted with use of a weak acid etchant, the transparent conductive film described above will have almost no residue due to etching.

It is preferable that the acidic etchant contains any one or more types of an oxalic acid, a mixed acid composed of phosphoric acid, acetic acid, and nitric acid, and a di-ammonium cerium (IV) nitrate.

For example, the oxalic acid concentration in the etchant containing oxalic acid is preferably 1 to 10 mass percent, and more preferably 1 to 5 mass percent. This is because if the oxalic acid concentration is less than 1 mass percent, the etching speed of the transparent conductive film may become slow in some cases, and if it exceeds 10 mass percent, the crystals of the oxalic acid may be deposited in the solution of the etchant containing oxalic acid in some cases.

### (Heat Treatment)

With the transparent conductive film of the present invention, the transparent conductive film may be subjected to heat treatment in which the formed transparent conductive film composed of an indium oxide containing gallium, or the transparent conductive film composed of an indium oxide containing gallium and tin, are etched to thereby form a transparent pixel electrode, and then the substrate is heated to a temperature ranging from 200 to 500° C.

By conducting this type of heat treatment, as described above, the property of the transparent conductive film formed with an indium oxide containing gallium can be brought to an amorphous state where microcrystals, which cannot be observed by means of X-ray diffraction, are present, and the property of the transparent conductive film formed with an indium oxide containing gallium and tin can be brought to a crystalline state.

In order to maintain the transparent conductive film composed of an indium oxide containing gallium at an amorphous state as described above, an appropriate temperature needs to be selected within the above temperature range, according to the gallium content. The transparent conductive film of the present invention composed of an indium oxide containing gallium shows, even with a composition with the lowest gallium content where the Ga/(In+Ga) atomic ratio is 0.10, the crystallization temperature is 220° C., which is higher than that of ITO, which is approximately 190° C. That is to say, with this composition, by conducting the heat treatment at a temperature no more than the crystallization temperature of 220° C., it is possible to maintain the amorphous state containing microcrystals without crystallization. The crystallization temperature becomes higher according to the increase in the gallium content. Therefore, as the gallium content increases, the upper limit of the heat treatment temperature, at which the amorphous state containing microcrystals can be maintained, becomes higher.

The heat treatment temperature of the transparent conductive film is set to 200° C. to 500° C. because if the heat treatment is conducted at a temperature lower than 200° C., microcrystals may not be produced in the transparent conductive film or the transparent conductive film may not be sufficiently crystallized, and there is also a possibility that light transmission of the transparent conductive film in the ultraviolet region cannot be made sufficiently high. On the other hand, if the heat treatment is conducted at a temperature exceeding 500° C., a problem arises in that there may be excessive interdiffusion between the constituent element of the transparent conductive film and the metallic wiring or barrier metal in contact therewith, and this may lead to more significant problems, such as an increase in specific resistance and contact resistance, in the steps of manufacturing a thin film transistor substrate.

In particular, in those cases where the heat treatment is conducted at a temperature exceeding 300° C., within the atmosphere containing oxygen, the problem of an increase in the specific resistance and contact resistance due to oxidization of the transparent conductive film or the metallic wiring or barrier metal in contact therewith, becomes more significant. Therefore, at a temperature above 300° C. in particular, heat treatment is preferably conducted within an atmosphere which does not contain oxygen.

### 3. Semiconductor Layer

In the thin film transistor substrate of the present invention, the semiconductor layer formed on the transparent substrate may be of amorphous silicon (hereunder, this may be referred to as a-Si in some cases) or polysilicon (hereunder, this may be referred to as p-Si in some cases), or further, it may be of an oxide such as amorphous InGaZn oxide (hereunder, this may be referred to as a-IGZO in some cases) or zinc oxide crystalline film.

### 4. Wiring

Moreover, in the thin film transistor substrate of the present invention, aluminum, which is inexpensive and has a low level of electrical resistance, is normally used for the wiring formed on the transparent substrate. However, an alloy with neodymium or cerium added to aluminum, which is capable of suppressing hillocks, or an alloy with nickel and a rare earth element such as La added to aluminum, which suppresses hillocks and increase in contact resistance, is also preferable.

Moreover, in those cases where low-temperature polysilicon is applied to the semiconductor layer formed on the transparent substrate, chrome, molybdenum, titanium, or tantalum may be used for the wiring formed on the transparent substrate as necessary.

### 5. Thin Film Transistor Type Liquid Crystal Display Device

A thin film transistor type liquid crystal display device of the present invention is characterized in that there are provided the above described thin film transistor substrate, a color filter substrate having a coloring pattern of a plurality of colors provided thereon, and a liquid crystal layer sandwiched between the thin film transistor substrate and the color filter substrate.

In the manufacturing step of the above thin film transistor substrate, etching defects such as breakage in the aluminum wiring hardly occur. Therefore, with use of this type of thin film transistor substrate, it is possible to manufacture a high-performance thin film transistor type liquid crystal display device having low displaying defects.

### EXAMPLES

Hereunder, the present invention is described in detail, with reference to examples and the accompanying drawings.

### Example 1

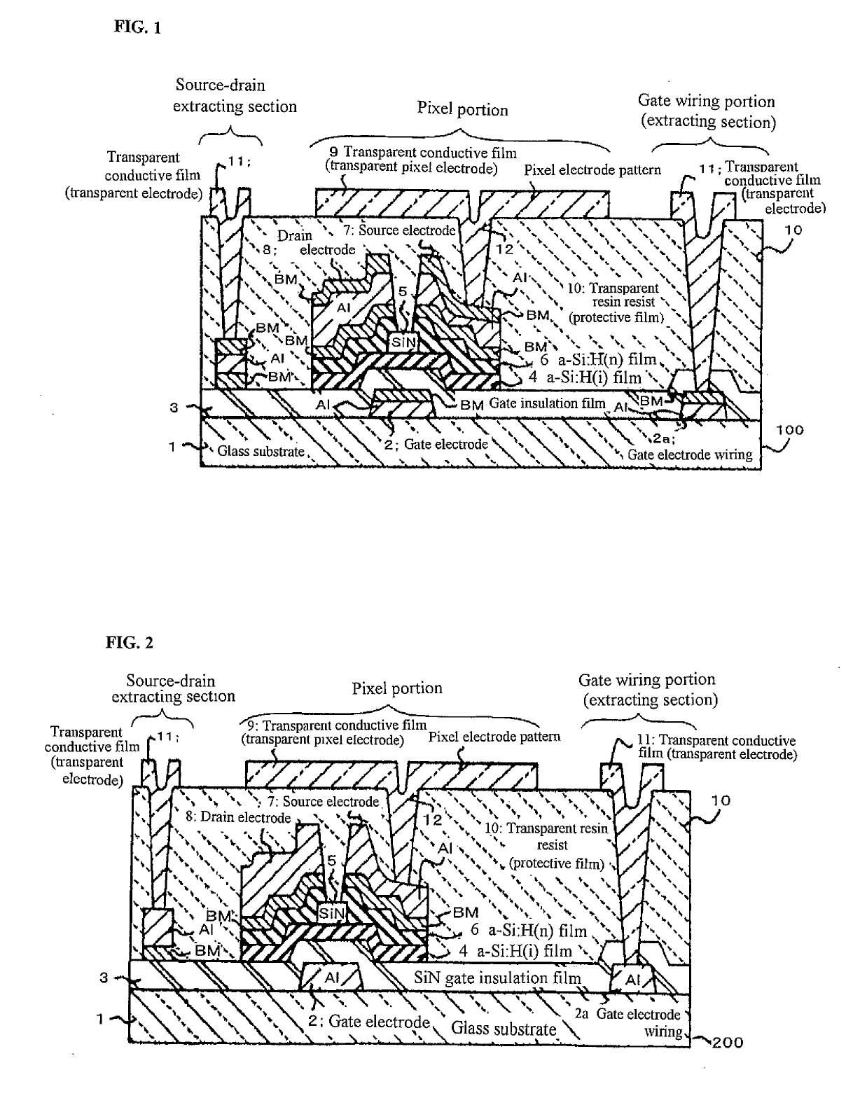

FIG. 1 shows a cross-sectional view of the vicinity of an a-Si TFT (amorphous silicon thin film transistor) active matrix substrate 100 in this Example 1. A metallic aluminum (Al) and a barrier metal BM (using metallic molybdenum (MO)) were sequentially formed with film thicknesses respectively of 150 nm and 50 nm on a translucent glass substrate 1 by means of a direct-current sputtering method.

Next, the metallic Al/metallic Mo two-layered film formed as above was etched in the shape shown in FIG. 1 by means of a photo-etching method, using a phosphoric acid, acetic acid, nitric acid, and water (volume ratio 12:6:1:1) based solution as an etching liquid, to thereby form a gate electrode 2 and a gate electrode wiring 2a.

Subsequently, a silicon nitride (SiN) film to serve as a gate insulation film 3 with a film thickness of 300 nm was formed on the glass substrate 1, the gate electrode 2, and the gate electrode wiring 2a by means of a glow-discharge CVD method. Next, on this gate insulation film 3, there was formed an a-Si:H (i) film 4 with a film thickness of 350 nm, and further a silicon nitride film (SiN film) to serve as a channel protective layer 5 was formed on the a-Si:H (i) film 4 with a film thickness of 300 nm.

At this time, as the discharge gas, a SiH₄—NH₃—N₂ based mixed gas was used for the gate insulation film 3 and the channel protective layer 5 formed from the SiN film, and meanwhile, a SiH₄—N₂ based mixed gas was used for the a-Si:H (i) film 4. Moreover, the channel protective layer 5 formed from this SiN film was etched by means of dry etching with use of a CHF based gas, to thereby form the shape shown in FIG. 1.

Subsequently, an a-Si:H (n) film 6 with a film thickness of 300 nm was formed on the a-Si:H (i) film 4 and the channel protective layer 5, using a SiH₄—H₂—PH₃ based mixed gas.

Next, on the formed a-Si:H (n) film 6, further, there were sequentially formed a metallic Mo/metallic Al/metallic Mo three-layered film by means of the direct-current sputtering method, in which the film thickness of the top and bottom Mo layers was 50 nm, and the film thickness of the intermediate Al layer was 200 nm.

This metallic Mo/metallic Al/metallic Mo three-layered film formed as above was then etched in the shape shown in FIG. 1 by means of the photo-etching method, using a phosphoric acid, acetic acid, nitric acid, and water (volume ratio 9:8:1:2) based solution as an etching liquid, to thereby form a pattern of a source electrode 7 and a pattern of a drain electrode 8.

Furthermore, by using both of a dry etching method with use of a CHF based gas and a wet etching method with use of a hydrazine (NH₂NH₂.H₂O) solution, etching was conducted on the a-Si:H (i) film 4 and the a-Si:H (n) film 6 formed from the a-Si:H film, to thereby form patterns of the a-Si:H (i) film 4 and the a-Si:H (n) film 6 in the shape shown in FIG. 1. Moreover, with use of a transparent resin resist 10, a protective film was formed, and further a pattern of a through hole and the like was formed as shown in FIG. 1.

Next, on the substrate which underwent the above treatment, there was formed an amorphous transparent conductive film 9 composed of an indium oxide containing gallium, by means of the direct-current sputtering method. The used target was an oxide sintered body in which the gallium content in the target was prepared to be 0.10 in terms of the Ga/(In+Ga) atomic ratio.

An indium oxide powder and a gallium oxide powder were adjusted to have an average grain diameter of 1 μm or less so as to serve as raw material powders. These powders were prepared so that the gallium content was 0.10 in terms of the Ga/(In+Ga) atomic ratio, and these powders and water were placed in a resin-made pot to be mixed in a wet-type ball mill. At this time, a hard ZrO₂ ball was used, and the mixing time was 18 hours. After mixing, the slurry was taken out, and then filtration, drying, and granulation were performed. Then, the granulated material was subjected to cold isostatic pressing with a pressure of 3 ton/cm² so as to be shape-formed.

Next, the shape-formed body was sintered as described below. The shape-formed body was sintered for 20 hours at a sintering temperature of 1,400° C. within an atmosphere in which oxygen was introduced to the air inside the sintering furnace at a ratio of 5 liter/min per furnace volume 0.1 m³. At this time, the sintering temperature was raised at 1° C./min. Then, introduction of oxygen was stopped when conducting cooling after sintering, and the temperature was lowered to 1,000° C. at 10° C./min.

The obtained oxide sintered body was then processed into a size with a diameter of 152 mm and a thickness of 5 mm, and the sputtering surface was polished with a cup grindstone so that the maximum height Rz became 3.0 μm or less. The processed oxide sintered body was bonded on a backing plate made of oxygen-free copper, using metallic indium, to thereby provide a sputtering target.

The relative density of this target was found to be 98% (7.0 g/cm³). Moreover, it was revealed as a result of an X-ray diffraction measurement that in the target, an In₂O₃ phase of bixbyite type structure was present and serving as the primary crystalline phase, and further, a GaInO₃ phase of β-Ga₂O₃ type structure, or a GaInO₃ phase and (Ga, In)₂O₃ phase were present and serving as disperse phases. As a result of actually conducting an SEM observation on the oxide sintered body, these disperse phases were confirmed to be composed of crystal grains with an average grain diameter of 5 μm or less.

In the direct-current sputtering, this oxide sintered body target was arranged and used on a planar magnetron type cathode, to thereby form the transparent conductive film 9 with a film thickness of 100 nm. At this time, as the discharge gas used in the direct-current sputtering, there was used an argon-oxygen mixed gas, the oxygen flow ratio of which was adjusted to 2.5%. With use of the oxide sintered body target having this type of structure above, the direct-current sputtering was conducted at room temperature without applying heat to the substrate. The substrate temperature was 25° C. During the film formation, electrical discharge was stable, and no nodules were found on the target surface.

The composition of the transparent conductive film 9 composed of the indium oxide containing gallium, which was formed by the above direct-current sputtering, was found to be similar to that of the oxide sintered body, which was used as the target. When this transparent conductive film 9 was measured by means of an X-ray diffraction method, no peak due to reflection derived from crystals was observed, and the film was found to be amorphous. Moreover, the specific resistance of this transparent conductive film 9 was found to be approximately 4.5×10⁻⁴ Ω·cm, and it was confirmed to be a film which can be sufficiently used as an electrode.

This transparent conductive film 9 composed of an indium oxide containing gallium was etched so as to have a transparent pixel electrode pattern, by means of an etching method, using a solution with 3.2 mass percent oxalic acid as an etchant. Thereby, the transparent pixel electrode pattern formed with the amorphous electrode of the transparent conductive film 9 shown in FIG. 1 was formed.

At this time, the required pattern was formed so that the pattern of the source electrode 7 and the transparent pixel electrode pattern formed with the transparent conductive film 9 were electrically connected. At this time, the source electrode 7 and drain electrode 8 containing metallic Al did not elute in the etching liquid. The solution with 3.2 mass percent oxalic acid corresponds to an example of the acidic etchant containing oxalic acid.

Next, the substrate was heated to a temperature of 200° C., and heat treatment was conducted on the transparent conductive film 9 for 30 minutes within a vacuum atmosphere. The specific resistance of the transparent conductive film 9 after the heat treatment was approximately 3.9×10⁻⁴ Ω·cm. When measurement was conducted by means of the X-ray diffraction method, no peak due to reflection derived from crystals was observed, and the film was found to be amorphous. Furthermore, when an observation was made on an AFM (Nanoscope III, product of Digital Instruments Co., Ltd.), the presence of microcrystals of an indium oxide phase was confirmed.

When the contact resistance was measured on another test, a good result was found with a low value of approximately 18Ω. When Ti, Cr, Ta, and W were applied as other barrier metals, excellent results as with Mo were obtained. The contact resistances in the case of applying Ti, Cr, Ta, and W were respectively found to be approximately 18Ω, approximately 19Ω, approximately 25Ω, and approximately 30Ω.

After this, an SiN passivation film (not shown in the drawing) and a light shielding pattern (not shown in the drawing) were formed, and the a-Si TFT active matrix substrate 100 shown in FIG. 1 was manufactured. On the glass substrate 1 in this a-Si TFT active matrix substrate 100, the pattern of the pixel portion and the like shown in FIG. 1 is regularly formed. That is to say, the a-Si TFT active matrix substrate 100 of Example 1 is of an array substrate. This a-Si TFT active matrix substrate 100 corresponds to an example of a suitable thin film transistor substrate.

A liquid crystal layer and a color filter substrate were provided on this a-Si TFT active matrix substrate 100, and thereby a TFT-LCD type flat display was manufactured. This TFT-LCD type flat display corresponds to an example of a thin film transistor type liquid crystal display device. A lighting test was conducted on this TFT-LCD type flat display, and as a result, no defects were found in the transparent pixel electrode, and excellent display was performed.

### Example 2

An a-Si TFT active matrix substrate 100 was fabricated in a manner similar to that of Example 1 except that there was used an oxide sintered body prepared so that the gallium content in the composition thereof was 0.20 in terms of the Ga/(In+Ga) atomic ratio unlike the oxide sintered body used in the above Example 1. The structure and characteristics of this oxide sintered body were similar to the oxide sintered body in Example 1.

When the transparent conductive film 9 composed of an indium oxide containing gallium was formed by means of direct-current sputtering under the condition similar to that of Example 1, electrical discharge was stable, and no nodules were found on the target surface.

Moreover, the composition of the transparent conductive film 9 after film formation was similar to that of the oxide sintered body used as the target. When this transparent conductive film 9 was analyzed by means of an X-ray diffraction method, no peak due to reflection derived from crystals was observed, and the film was found to be amorphous. Moreover, the specific resistance of this transparent conductive film 9 was found to be approximately 7.8×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

Furthermore, the substrate was heated to a temperature of 300° C., and heat treatment was conducted for 30 minutes within a vacuum atmosphere. The specific resistance of the transparent conductive film 9 after the heat treatment was approximately 5.3×10⁻⁴ Ω·cm. Moreover, the property of the transparent conductive film 9 after the heat treatment was similar to that in Example 1.

When the contact resistance was measured on another test, a good result was found with a low value of approximately 20Ω. When Ti, Cr, Ta, and W were applied as other barrier metals, excellent results as with Mo were obtained. The contact resistances in the case of applying Ti, Cr, Ta, and W were respectively found to be approximately 19Ω, approximately 21Ω, approximately 28Ω, and approximately 31Ω.

A lighting test was conducted on the obtained TFT-LCD type flat display, and as a result, no defects were found in the transparent pixel electrode, and excellent display was performed.

### Example 3

An a-Si TFT active matrix substrate 100 was fabricated in a manner similar to that of Example 1 and Example 2 except that: there was used an oxide sintered body which was prepared so that the gallium content in the composition thereof was 0.10 in terms of the Ga/(In+Ga+Sn) atomic ratio, and the tin content was 0.05 in terms of the Sn/(In+Ga+Sn) atomic ratio, unlike the oxide sintered body used in the above Example 1 and Example 2; and heat treatment was conducted after having formed the transparent pixel electrode. The relative density of the target of this oxide sintered body was 98%, and it was revealed as a result of an X-ray diffraction measurement that in the target, an In₂O₃ phase of bixbyite type structure was present and serving as the primary crystalline phase, and further, a GaInO₃ phase of β-Ga₂O₃ type structure, or a GaInO₃ phase and (Ga, In)₂O₃ phase were present and serving as disperse phases. As a result of conducting an SEM observation on the oxide sintered body, these disperse phases were confirmed to be composed of crystal grains with an average grain diameter of 5 μm or less. Moreover, as a result of conducting an analysis on the crystal grain composition, using an EDS (energy dispersive x-ray spectrometer) analyzer attached to the SEM, it was confirmed that all of the In₂O₃ phase of bixbyite type structure and the GaInO₃ phase, or the (Ga, In)₂O₃ phase contained tin.

When the transparent conductive film 9 composed of an indium oxide containing gallium and tin was formed by means of direct-current sputtering under the condition similar to that of Example 1 and Example 2, electrical discharge was stable, and no nodules were found on the target surface.

Moreover, the composition of the transparent conductive film 9 after film formation was similar to that of the oxide sintered body used as the target. When this transparent conductive film 9 was measured by means of an X-ray diffraction method, no peak due to reflection derived from crystals was observed, and the film was found to be amorphous. Moreover, the specific resistance of this transparent conductive film 9 was found to be approximately 5.2×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

In Example 3, after this, heat treatment was conducted for 30 minutes at a temperature of 280° C. The specific resistance of the transparent conductive film 9 after the heat treatment was approximately 3.1×10⁻⁴ Ω·cm, and it was confirmed that it was more suitable as an electrode. Moreover, when a measurement was conducted by means of an X-ray diffraction method, reflection derived from the In₂O₃ phase was observed, and it was confirmed that it became a crystalline film. Moreover, when the contact resistance was measured on another test, a good result was found with a low value of approximately 17Ω. When Ti, Cr, Ta, and W were applied as other barrier metals, excellent results as with Mo were obtained. The contact resistances in the case of applying Ti, Cr, Ta, and W were respectively found to be approximately 17Ω, approximately 16Ω, approximately 22Ω, and approximately 26Ω.

Furthermore, a lighting test was conducted on the obtained TFT-LCD type flat display, and as a result, no defects were found in the transparent pixel electrode, and excellent display was performed.

### Example 4

FIG. 2 shows a cross-sectional view of the vicinity of an a-Si TFT (amorphous silicon thin film transistor) active matrix substrate 200 in this Example 4. This a-Si TFT active matrix substrate 200 is of a structure similar to that of the substrate 100 in Example 1 except that: the barrier metal BM (metallic Mo) was not formed on the gate electrode, and there was provided a single layer of metallic Al; and the barrier metal BM (metallic Mo) was not formed on the drain electrode and source electrode, and there were provided two-layered films of metallic Mo/metallic Al. Therefore, this example is basically similar to Example 1 except that formation of the barrier metal BM layer is omitted in the manufacturing method. Moreover, the composition of the transparent conductive film 9 on the a-Si TFT active matrix substrate 200 in the present Example 4 is the same as the composition of the transparent conductive film 9 on the a-Si TFT active matrix substrate 100 in the above Example 1.

On a translucent glass substrate 1, there was formed a metallic Al film with a film thickness of 150 nm, by means of a direct-current sputtering method.

Next, the Al film formed as above was etched in a shape shown in FIG. 2 by means of a photo-etching method, using a phosphoric acid, acetic acid, nitric acid, and water (volume ratio 12:6:1:1) based solution as an etching liquid, to thereby form a gate electrode 2 and a gate electrode wiring 2a.

When the transparent conductive film 9 composed of an indium oxide containing gallium was formed by means of direct-current sputtering, using a target similar to that of Example 1 under the condition similar to that of Example 1, electrical discharge was stable, and no nodules were found on the target surface.

Moreover, the composition of the transparent conductive film 9 after film formation was similar to that of the oxide sintered body used as the target. When this transparent conductive film 9 was measured by means of an X-ray diffraction method, no peak due to reflection derived from crystals was observed, and the film was found to be amorphous. Moreover, the specific resistance of this transparent conductive film 9 was found to be approximately 4.5×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

Furthermore, heat treatment was conducted under the condition similar to that of Example 1. The specific resistance of the transparent conductive film 9 after the heat treatment was approximately 5.3×10⁻⁴ Ω·cm. Moreover, the property of the transparent conductive film 9 after the heat treatment was similar to that in Example 1.

When the contact resistance was measured on another test, the result was approximately 90Ω. This value is higher than that in Examples 1 to 3, however, the level of this result is good, and this is very unlikely to create a problem from a practical standpoint.

After this, an SiN passivation film (not shown in the drawing) and a light shielding pattern (not shown in the drawing) were formed, and the a-Si TFT active matrix substrate 200 shown in FIG. 2 was manufactured. On the glass substrate 1 in this a-Si TFT active matrix substrate 200, the pattern of the pixel portion and the like shown in FIG. 2 is regularly formed. That is to say, the a-Si TFT active matrix substrate 200 of Example 4 is of an array substrate.

A liquid crystal layer and a color filter substrate were provided on this a-Si TFT active matrix substrate 200, and thereby a TFT-LCD type flat display was manufactured. A lighting test was conducted on this TFT-LCD type flat display, and as a result, no defects were found in the transparent pixel electrode, and excellent display was performed.

### Example 5

An a-Si TFT active matrix substrate 100 was fabricated under a condition similar to that of Example 3 except that there was used an oxide sintered body prepared so that the gallium content in the composition thereof was 0.05 in terms of the Ga/(In+Ga+Sn) atomic ratio, and the tin content was 0.09 in terms of the Sn/(In+Ga+Sn) atomic ratio, unlike the oxide sintered body used in the above Example 3. The relative density of the target of this oxide sintered body was 99%, and it was revealed as a result of an X-ray diffraction measurement that in the target, an In₂O₃ phase of bixbyite type structure was present and serving as the primary crystalline phase, and further, a GaInO₃ phase of β-Ga₂O₃ type structure, or a GaInO₃ phase and (Ga, In)₂O₃ phase were present and serving as disperse phases. As a result of conducting an SEM observation on the oxide sintered body, these disperse phases were confirmed to be composed of crystal grains with an average grain diameter of 5 μm or less. Moreover, as a result of conducting an analysis on the crystal grain composition, using an EDS (energy dispersive x-ray spectrometer) analyzer attached to the SEM, it was confirmed that all of the In₂O₃ phase of bixbyite type structure and the GaInO₃ phase, or the (Ga, In)₂O₃ phase contained tin.

When the transparent conductive film 9 composed of an indium oxide containing gallium and tin was formed by means of direct-current sputtering in a manner similar to that of Example 3, electrical discharge was stable, and no nodules were found on the target surface.

Moreover, the composition of the transparent conductive film 9 after film formation was similar to that of the oxide sintered body used as the target. When this transparent conductive film 9 was measured by means of an X-ray diffraction method, no peak due to reflection derived from crystals was observed, and the film was found to be amorphous. Moreover, the specific resistance of this transparent conductive film 9 was found to be approximately 4.9×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

In Example 5, after this, heat treatment was conducted for 30 minutes at a temperature of 300° C. The specific resistance of the transparent conductive film 9 after the heat treatment was approximately 2.4×10⁻⁴ Ω·cm, and it was confirmed that it was more suitable as an electrode. Moreover, when a measurement was conducted by means of an X-ray diffraction method, reflection derived from the In₂O₃ phase was observed, and it was confirmed that it became a crystalline film. Moreover, when the contact resistance was measured on another test, a good result was found with a low value of approximately 15Ω. When Ti, Cr, Ta, and W were applied as other barrier metals, excellent results as with Mo were obtained. The contact resistances in the case of applying Ti, Cr, Ta, and W were respectively found to be approximately 15Ω, approximately 14Ω, approximately 21Ω, and approximately 22Ω.

Furthermore, a lighting test was conducted on the obtained TFT-LCD type flat display, and as a result, no defects were found in the transparent pixel electrode, and excellent display was performed.

### Example 6

An a-Si TFT active matrix substrate 100 was fabricated in a manner similar to that of Example 3 except that there was used an oxide sintered body prepared so that the gallium content in the composition thereof was 0.02 in terms of the Ga/(In+Ga+Sn) atomic ratio, and the tin content was 0.09 in terms of the Sn/(In+Ga+Sn) atomic ratio, unlike the oxide sintered body used in the above Example 3. The relative density of the target of this oxide sintered body was 98%, and it was revealed as a result of an X-ray diffraction measurement that in the target, an In₂O₃ phase of bixbyite type structure was present and serving as the primary crystalline phase, and further, a GaInO₃ phase of β-Ga₂O₃ type structure, or a GaInO₃ phase and (Ga, In)₂O₃ phase were present and serving as disperse phases. As a result of conducting an SEM observation on the oxide sintered body, these disperse phases were confirmed to be composed of crystal grains with an average grain diameter of 5 μm or less. Moreover, as a result of conducting an analysis on the crystal grain composition, using an EDS (energy dispersive x-ray spectrometer) analyzer attached to the SEM, it was confirmed that all of the In₂O₃ phase of bixbyite type structure and the GaInO₃ phase, or the (Ga, In)₂O₃ phase contained tin.

When the transparent conductive film 9 composed of an indium oxide containing gallium and tin was formed by means of direct-current sputtering in a manner similar to that of Example 3, electrical discharge was stable, and no nodules were found on the target surface.

Moreover, the composition of the transparent conductive film 9 after film formation was similar to that of the oxide sintered body used as the target. When this transparent conductive film 9 was measured by means of an X-ray diffraction method, no peak due to reflection derived from crystals was observed, and the film was found to be amorphous. Moreover, the specific resistance of this transparent conductive film 9 was found to be approximately 4.4×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

In Example 6, after this, heat treatment was conducted for 30 minutes at a temperature of 250° C. The specific resistance of the transparent conductive film 9 after the heat treatment was approximately 2.1×10⁻⁴·cm, and it was confirmed that it was more suitable as an electrode. Moreover, when a measurement was conducted by means of an X-ray diffraction method, reflection derived from the In₂O₃ phase was observed, and it was confirmed that it became a crystalline film. Moreover, when the contact resistance was measured on another test, a good result was found with a low value of approximately 15Ω. When Ti, Cr, Ta, and W were applied as other barrier metals, excellent results as with Mo were obtained. The contact resistances in the case of applying Ti, Cr, Ta, and W were respectively found to be approximately 15Ω, approximately 15Ω, approximately 22Ω, and approximately 22Ω.

Furthermore, a lighting test was conducted on the obtained TFT-LCD type flat display, and as a result, no defects were found in the transparent pixel electrode, and excellent display was performed.

### Example 7

An a-Si TFT active matrix substrate 100 was fabricated in a manner similar to that of Example 3 except that there was used an oxide sintered body prepared so that the gallium content in the composition thereof was 0.08 in terms of the Ga/(In+Ga+Sn) atomic ratio, and the tin content was 0.11 in terms of the Sn/(In+Ga+Sn) atomic ratio, unlike the oxide sintered body used in the above Example 3. The relative density of the target of this oxide sintered body was 98%, and it was revealed as a result of an X-ray diffraction measurement that in the target, an In₂O₃ phase of bixbyite type structure was present and serving as the primary crystalline phase, and further, a GaInO₃ phase of β-Ga₂O₃ type structure, or a GaInO₃ phase and (Ga, In)₂O₃ phase were present and serving as disperse phases. As a result of conducting an SEM observation on the oxide sintered body, these disperse phases were confirmed to be composed of crystal grains with an average grain diameter of 5 μm or less. Moreover, as a result of conducting an analysis on the crystal grain composition, using an EDS (energy dispersive x-ray spectrometer) analyzer attached to the SEM, it was confirmed that all of the In₂O₃ phase of bixbyite type structure and the GaInO₃ phase, or the (Ga, In)₂O₃ phase contained tin.

When the transparent conductive film 9 composed of an indium oxide containing gallium and tin was formed by means of direct-current sputtering in a manner similar to that of Example 3, electrical discharge was stable, and no nodules were found on the target surface.

Moreover, the composition of the transparent conductive film 9 after film formation was similar to that of the oxide sintered body used as the target. When this transparent conductive film 9 was measured by means of an X-ray diffraction method, no peak due to reflection derived from crystals was observed, and the film was found to be amorphous. Moreover, the specific resistance of this transparent conductive film 9 was found to be approximately 6.4×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

In Example 7, after this, heat treatment was conducted for 30 minutes at a temperature of 400° C. The heat treatment was conducted with meticulous care at a comparatively high temperature of 400° C. so that the treatment would not be affected by oxidization caused by residual oxygen or water content within the furnace. The specific resistance of the transparent conductive film 9 after the heat treatment was approximately 2.1×10⁻⁴ Ω·cm, and it was confirmed that it was more suitable as an electrode. Moreover, when a measurement was conducted by means of an X-ray diffraction method, reflection derived from the In₂O₃ phase was observed, and it was confirmed that it became a crystalline film. Moreover, when the contact resistance was measured on another test, a good result was found with a low value of approximately 16Ω. When Ti, Cr, Ta, and W were applied as other barrier metals, excellent results as with Mo were obtained. The contact resistances in the case of applying Ti, Cr, Ta, and W were respectively found to be approximately 17Ω, approximately 17Ω, approximately 26Ω, and approximately 28Ω.

Furthermore, a lighting test was conducted on the obtained TFT-LCD type flat display, and as a result, no defects were found in the transparent pixel electrode, and excellent display was performed.

### Example 8

FIG. 2 shows a cross-sectional view of the vicinity of an a-Si TFT (amorphous silicon thin film transistor) active matrix substrate 200 in this Example 8, which is similar to that in Example 4. This a-Si TFT active matrix substrate 200 is of a structure such that: the barrier metal BM (metallic Mo) was not formed on the gate electrode, and there was provided a single layer of metallic Al; and the barrier metal BM (metallic Mo) was not formed on the drain electrode and source electrode, and there were provided two-layered films of metallic Mo/metallic Al.

In the present Example 8, there was used the oxide sintered body of Example 5, rather than that in Example 4. That is to say, there was used an oxide sintered body prepared so that the gallium content in the composition thereof was 0.05 in terms of the Ga/(In+Ga+Sn) atomic ratio, and the tin content was 0.09 in terms of the Sn/(In+Ga+Sn) atomic ratio. The manufacturing method was basically similar to that of Example 4 except that after having formed the transparent pixel electrode pattern by means of an etching method, heat treatment was conducted for 30 minutes at a temperature of 300° C.

On a translucent glass substrate 1, there was formed a metallic Al film with a film thickness of 150 nm, by means of a direct-current sputtering method.

Next, the Al film formed as above was etched in a shape shown in FIG. 2 by means of a photo-etching method, using a phosphoric acid, acetic acid, nitric acid, and water (volume ratio 12:6:1:1) based solution as an etching liquid, to thereby form a gate electrode 2 and a gate electrode wiring 2a.

When the transparent conductive film 9 composed of an indium oxide containing gallium and tin was formed by means of direct-current sputtering in a manner similar to that of Example 5, electrical discharge was stable, and no nodules were found on the target surface.

Moreover, the composition of the transparent conductive film 9 after film formation was similar to that of the oxide sintered body used as the target. When this transparent conductive film 9 was measured by means of an X-ray diffraction method, no peak due to reflection derived from crystals was observed, and the film was found to be amorphous. Moreover, the specific resistance of this transparent conductive film 9 was found to be approximately 4.9×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

After that, heat treatment was conducted for 30 minutes at a temperature of 300° C. in a manner similar to that of Example 5. The specific resistance of the transparent conductive film 9 after the heat treatment was approximately 2.4×10⁻⁴ Ω·cm, and it was confirmed that it was more suitable as an electrode. Moreover, when a measurement was conducted by means of an X-ray diffraction method, reflection derived from the In₂O₃ phase was observed, and it was confirmed that it became a crystalline film. Moreover, when the contact resistance was measured on another test, a good result was found with a low value of approximately 15Ω. When the contact resistance was measured on another test, the result was approximately 72Ω. This value is higher than that in Examples 1 to 3, however, it is lower than the value seen in Example 4, and the level of this result is good and very unlikely to create a problem from a practical standpoint.

After this, an SiN passivation film (not shown in the drawing) and a light shielding pattern (not shown in the drawing) were formed, and the a-Si TFT active matrix substrate 200 shown in FIG. 2 was manufactured. On the glass substrate 1 in this a-Si TFT active matrix substrate 200, the pattern of the pixel portion and the like shown in FIG. 2 is regularly formed. That is to say, the a-Si TFT active matrix substrate 200 of Example 4 is of an array substrate.

A liquid crystal layer and a color filter substrate were provided on this a-Si TFT active matrix substrate 200, and thereby a TFT-LCD type flat display was manufactured. A lighting test was conducted on the obtained TFT-LCD type flat display, and as a result, no defects were found in the transparent pixel electrode, and excellent display was performed.

### Example 9

In the above Examples 1 to 8, there has been described the example in which the etchant used for etching the transparent conductive film 9 was a 3.2 wt % oxalic acid solution. However, a suitable etchant to be used for etching the transparent conductive film 9 may also be a mixed acid composed of phosphoric acid, acetic acid, and nitric acid, in addition to the above oxalic acid based solution, or it may also be a di-ammonium cerium nitrate (IV) solution. No problem was observed when these etchants were actually applied to the above Examples 1 to 8.

### Example 10

An a-Si TFT active matrix substrate 100 was fabricated in a manner similar to that of Example 1 except that there was used an oxide sintered body prepared so that the gallium content in the composition thereof was 0.35 in terms of the Ga/(In+Ga) atomic ratio unlike the oxide sintered body used in the above Example 1. The structure and characteristics of this oxide sintered body were similar to the oxide sintered body in Example 1.

When the transparent conductive film 9 composed of an indium oxide containing gallium was formed by means of direct-current sputtering under the condition similar to that of Example 1, electrical discharge was stable, and no nodules were found on the target surface.

Moreover, the composition of the transparent conductive film 9 after film formation was similar to that of the oxide sintered body used as the target. When this transparent conductive film 9 was analyzed by means of an X-ray diffraction method, no peak due to reflection derived from crystals was observed, and the film was found to be amorphous. Moreover, the specific resistance of this transparent conductive film 9 was found to be approximately 8.9×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid.

Furthermore, the substrate was heated to a temperature of 300° C., and heat treatment was conducted for 30 minutes within a vacuum atmosphere. The specific resistance of the transparent conductive film 9 after the heat treatment was approximately 6.1×10⁻⁴ Ω·cm. Moreover, the property of the transparent conductive film 9 after the heat treatment was similar to that in Example 1.

When the contact resistance was measured on another test, a good result was found with a low value of approximately 20Ω. When Ti, Cr, Ta, and W were applied as other barrier metals, excellent results as with Mo were obtained. The contact resistances in the case of applying Ti, Cr, Ta, and W were respectively found to be approximately 20Ω, approximately 23Ω, approximately 29Ω, and approximately 34Ω.

A lighting test was conducted on the obtained TFT-LCD type flat display, and as a result, no defects were found in the transparent pixel electrode, and excellent display was performed.

### Comparative Example 1

An a-Si TFT active matrix substrate 100 was fabricated under a condition similar to that in Example 1, except that there was used an oxide sintered body composed of indium oxide and zinc oxide which was prepared so that the zinc content in the target was 0.107 in terms of the Zn/(In+Zn) atomic ratio.

The relative density of this target was found to be 99% (6.89 g/cm³). Moreover, it was revealed as a result of an X-ray diffraction measurement that in the target, an In₂O₃ phase of bixbyite type structure was present and serving as the primary crystalline phase, and further, a In₂O₃(ZnO)ₘ (where m=2 to 7) phase composed of a hexagonal crystal lamellar compound was present and serving as a disperse phase. As a result of actually conducting an SEM observation on the oxide sintered body, these disperse phases were confirmed to be composed of crystal grains with an average grain diameter of 5 μm or less.

When the transparent conductive film 9 composed of an indium oxide and zinc oxide was formed by means of direct-current sputtering in a manner similar to that of Example 1, electrical discharge was stable, and no nodules were found on the target surface.

Moreover, the composition of the transparent conductive film 9 after film formation was similar to that of the oxide sintered body used as the target. When this transparent conductive film 9 was analyzed by means of an X-ray diffraction method, no peak due to reflection derived from crystals was observed, and the film was found to be amorphous. Moreover, the specific resistance of this transparent conductive film 9 was found to be approximately 3.8×10⁻⁴ Ω·cm, and it was confirmed to be a film which can be sufficiently used as an electrode.

Furthermore, also when the transparent pixel electrode pattern was formed by means of an etching method, the source electrode 7 and drain electrode 8 containing metallic Al did not elute in the etching liquid. However, when the contact resistance was measured on another test, the result showed a value of several MΩ, which is extremely high compared to those in Examples 1 to 4 and cannot be applied to the thin film transistor substrate of the present invention.

Furthermore, a lighting test was conducted on the obtained TFT-LCD type flat display, and as a result, many defects were found in the transparent pixel electrode and good display performance could not be achieved. The cause of this was investigated, and it was revealed that defects in the transparent pixel electrode were caused by the increase in contact resistance between the transparent conductive film and the barrier metal Mo.

### Comparative Example 2

An a-Si TFT active matrix substrate 200 was fabricated in a manner similar to that in Example 4 except that there was used an oxide sintered body, which was ITO composed of indium oxide and tin oxide, prepared so that the tin oxide content in the composition thereof was 10 mass percent in terms of the mass ratio with respect to the oxide sintered body used in the Example 4. The relative density of this target was found to be 99.6% (7.12 g/cm³). Moreover, it was revealed as a result of an X-ray diffraction measurement that in the target, an In₂O₃ phase of bixbyite type structure was present.

When the transparent conductive film 9 composed of ITO was formed by means of direct-current sputtering in a manner similar to that of Example 4, electrical discharge was stable, and no nodules were found on the target surface.

Moreover, the composition of the transparent conductive film 9 was similar to that of the oxide sintered body used as the target. When this transparent conductive film 9 was analyzed by means of an X-ray diffraction method, no peak due to reflection derived from crystals was observed, and the film was found to be amorphous. When the film surface was observed using an AFM, it was revealed that microcrystals were present in this transparent conductive film 9 in a state immediately after film formation. Moreover, the specific resistance of this transparent conductive film 9 was found to be approximately 7.2×10⁻⁴ Ω·cm, and it was confirmed to be a film which can be sufficiently used as an electrode.

Another etching test was conducted before forming the transparent pixel electrode pattern. As a result, in a case of using a 3.2 wt % oxalic acid solution shown in Example 9, microcrystals were present in the transparent conductive film 9 composed of ITO, and consequently etching could not be successfully conducted. Consequently, another test was further conducted with use of a solution composed of strong acid FeCl₃ and HCl, and it was confirmed that etching could be successfully conducted. Accordingly, the etching liquid was changed to the solution composed of FeCl₃ and HCl and the transparent pixel electrode pattern was formed by means of an etching method. As a result, it was observed that the source electrode 7 and drain electrode 8 containing metallic Al were eluting into the etching liquid, and it was revealed that it would come to a state where application of this to the thin film transistor substrate of the present invention was impossible. Moreover, when the contact resistance was measured on another test, the result showed a value of several MΩ, which is extremely high compared to those in Examples 1 to 4 and cannot be applied to the thin film transistor substrate of the present invention.

Furthermore, a lighting test was conducted on the obtained TFT-LCD type flat display, and as a result, many defects were found in the transparent pixel electrode and good display performance could not be achieved. The cause of this was investigated, and it was revealed that defects in the pixel electrode were caused by breakage in the aluminum wiring and the increase in contact resistance between the transparent conductive film and the aluminum wiring.

### Comparative Example 3

An a-Si TFT active matrix substrate 100 was fabricated in a manner similar to that of Example 1 except that there was used an oxide sintered body which was prepared using an indium oxide containing gallium and zinc so that the gallium content in the composition thereof was 0.20 in terms of the Ga/(In+Ga+Zn) atomic ratio, and the zinc content was 0.05 in terms of the Zn/(In+Ga+Zn) atomic ratio, unlike the oxide sintered body used in the above Example 1. The structure and characteristics of this oxide sintered body were similar to the oxide sintered body in Example 1.

When the transparent conductive film 9 composed of an indium oxide containing gallium was formed by means of direct-current sputtering under the condition similar to that of Example 1, electrical discharge was stable, and no nodules were found on the target surface.

Moreover, the composition of the transparent conductive film 9 after film formation was similar to that of the oxide sintered body used as the target. When this transparent conductive film 9 was analyzed by means of an X-ray diffraction method, no peak due to reflection derived from crystals was observed, and the film was found to be amorphous. Furthermore, the specific resistance of this transparent conductive film 9 was approximately 1.5×10⁻³ Ω·cm, which is higher than 1.0×10⁻³ Ω·cm, and it was revealed that the specific resistance was high as an electrode.

Also when the transparent pixel electrode pattern was formed by means of an etching method, the source electrode 7 and drain electrode 8 containing metallic Al did not elute in the etching liquid.

The substrate was heated to a temperature of 300° C., and heat treatment was conducted for 30 minutes within a vacuum atmosphere. However, the specific resistance of the transparent conductive film 9 after the heat treatment was approximately 1.3×10^{31 4}Ω·cm, and the specific resistance remained high. Moreover, the property of the transparent conductive film 9 after the heat treatment was similar to that in Example 1.

When the contact resistance was measured on another test, the result showed a value of several MΩ, which is extremely high and cannot be applied to the thin film transistor substrate of the present invention.

Furthermore, a lighting test was conducted on the obtained TFT-LCD type flat display, and as a result, many defects were found in the transparent pixel electrode and good display performance could not be achieved. The cause of this was investigated, and it was revealed that defects in the transparent pixel electrode were caused by the increase in contact resistance between the transparent conductive film and barrier metal Mo.

1. A thin film transistor substrate in which there is provided a transparent substrate, on the transparent substrate there are formed a gate electrode, a semiconductor layer, a source electrode, a drain electrode, a transparent pixel electrode, and a transparent electrode, and the transparent pixel electrode is formed with a transparent conductive film and is electrically connected to the source electrode or the drain electrode,
wherein the transparent conductive film which constitutes the transparent pixel electrode is composed of an indium oxide containing gallium.

2. A thin film transistor substrate according to claim 1, wherein the gallium content in the indium oxide containing gallium is 0.10 to 0.35 in terms of the Ga/(In+Ga) atomic ratio.

3. A thin film transistor substrate according to claim 1, wherein the transparent conductive film is amorphous.

4. A thin film transistor substrate in which there is provided a transparent substrate, on the transparent substrate there are formed a gate electrode, a semiconductor layer, a source electrode, a drain electrode, a transparent pixel electrode, and a transparent electrode, and the transparent pixel electrode is formed with a transparent conductive film and is electrically connected to the source electrode or the drain electrode,
wherein the transparent conductive film which constitutes the transparent pixel electrode is composed of an indium oxide containing gallium and tin.

5. A thin film transistor substrate according to claim 4, wherein the gallium content in the indium oxide containing gallium and tin is 0.02 to 0.30 in terms of the Ga/(In+Ga+Sn) atomic ratio, and the tin content is 0.01 to 0.11 in terms of the Sn/(In+Ga+Sn) atomic ratio.

6. A thin film transistor substrate according to claim 4, wherein the transparent conductive film is crystallized.

7. A thin film transistor substrate according to claim 1, wherein the transparent conductive film does not contain zinc.

8. A thin film transistor type liquid crystal display device which is provided with a thin film transistor substrate according to claim 1, a color filter substrate having a coloring pattern of a plurality of colors provided thereon, and a liquid crystal layer which is sandwiched between the thin film transistor substrate and the color filter substrate.

9. A method for manufacturing a thin film transistor substrate in which there is provided a transparent substrate, on the transparent substrate there are formed a gate electrode, a semiconductor layer, a source electrode, a drain electrode, a transparent pixel electrode, and a transparent electrode, and the transparent pixel electrode is formed with a transparent conductive film and is electrically connected to the source electrode or the drain electrode,
wherein there are included steps of:
forming an amorphous-state indium oxide film containing gallium, or an amorphous-state indium oxide film containing gallium and tin on the transparent substrate, to thereby form the transparent conductive film; and
etching the formed transparent conductive film with use of an acidic etchant, to thereby form the transparent pixel electrode.

10. A method for manufacturing a thin film transistor substrate according to claim 9, wherein the acidic etchant contains any one or more types of an oxalic acid, a mixed acid composed of phosphoric acid, acetic acid, and nitric acid, and a di-ammonium cerium (IV) nitrate.

11. A method for manufacturing a thin film transistor substrate according to claim 9, wherein there is included a step of conducting heat treatment on the transparent conductive film at a temperature of 200° C. to 500° C., after the step of forming the transparent pixel electrode.

12. A method of manufacturing a thin film transistor substrate according to claim 11, wherein in a case where the transparent conductive film is formed with the amorphous-state indium oxide containing gallium, microcrystals are produced in the transparent conductive film by the heat treatment, and this amorphous state thereof is maintained.

13. A method of manufacturing a thin film transistor substrate according to claim 11, wherein in a case where the transparent conductive film is formed with the amorphous-state indium oxide containing gallium and tin, the transparent conductive film is crystallized by the heat treatment.

14. A method for manufacturing a thin film transistor substrate according to claim 11, wherein the heat treatment is conducted within an atmosphere which does not contain oxygen.
